(19) United States
(12) Patent Application Publication
(10) Pub. No.: US 2008/0020567 A1
(43) Pub. Date: Jan. 24, 2008

(54) Method of Manufacturing a Semiconductor Device

(75) Inventors: Eun-Ji Jung, Gyeonggi-do (KR); Jong-Ho Yun, Gyeonggi-do (KR); Dae-Yong Kim, Gyeonggi-do (KR); Hyun-Su Kim, Gyeonggi-do (KR); Byung-Hee Kim, Seoul (KR); Eun-Ok Lee, Incheon (KR)

Correspondence Address: MYERS BIGEL SIBLEY & SAJOVEC, PO BOX 37428, RALEIGH, NC, 27627, US

(73) Assignee: Samsung Electronics Company, Ltd.

(21) Appl. No.: 11/777,536

(22) Filed: Jul. 13, 2007

(30) Foreign Application Priority Data
Jul. 21, 2006 (KR) 10-2006-0068458

(51) Int. Cl. H01L 21/441

(52) U.S. Cl. 438/664; 257/E21.477

(57) ABSTRACT

Provided are methods of manufacturing a semiconductor device. Some embodiments of such methods may include forming a preliminary gate pattern on a substrate. The preliminary gate pattern may include silicon. Methods may include forming an insulation layer pattern on the substrate after forming the preliminary gate pattern. The insulation layer pattern exposes an upper face of the preliminary gate pattern. Methods may include forming a metal layer on the upper face of the preliminary gate pattern via an electroless plating process. Methods may include forming a gate pattern including a metal silicide from a reaction between the preliminary gate pattern and the metal layer by performing a heat treatment process.

### CROSS-REFERENCE TO RELATED APPLICATIONS

This U.S. non-provisional patent application claims priority under 35 U.S.C. § 119 to Korean Patent Application No. 2006-68458, filed on Jul. 21, 2006, the entire contents of which are herein incorporated by reference.

### BACKGROUND OF THE INVENTION

The present invention relates to semiconductor devices and, more particularly, to methods of manufacturing semiconductor devices.

As semiconductor devices continue to develop, the integration degree in these devices may increase. Accordingly, gate pattern line widths in semiconductor devices may be reduced. In some cases, a reduction in line width may result in the use of a metal or a metal silicide instead of polysilicon for the gate pattern. Particularly, a fully silicided gate pattern including metal silicide may be employed in the semiconductor device to reduce resistance of the gate pattern.

Reference is now made to FIG. 1, which is a cross-sectional view illustrating a semiconductor device including a fully silicided gate pattern, as formed using a conventional method. For example, a fully silicided gate pattern may be formed as follows. A preliminary gate pattern 12 including silicon may be formed on a substrate 10. A spacer 14 may be formed on a sidewall of the preliminary gate pattern 12. An insulation layer pattern 16 that exposes primarily a top surface of the preliminary gate pattern 12 may be formed. A transition metal layer 18 may be formed on the insulation layer pattern 16, the preliminary gate pattern 12 and the spacer 14. A heat treatment process may be performed on the substrate 10 having the transition metal layer 18 and the preliminary gate pattern 12. In this maimer, the preliminary gate pattern 12 and the transition metal layer 18 may be reacted with each other. As a result, the fully silicided gate pattern may be formed. That is, the preliminary gate pattern 12 and the transition metal layer 18 may be converted into a gate pattern including a metal silicide by the heat treatment process. The transition metal layer 18 may be formed by a physical vapor deposition (PVD) process.

However, when a fully silicided gate pattern is formed using the above-mentioned method, out-diffusion of silicon may occur, and thus the metal silicide may be formed on the spacer 14 and the insulation layer pattern 16. The metal silicide formed on the spacer 14 and the insulation layer pattern 16 may not be sufficiently removed even using a stripping process. In this regard, the metal silicide formed on the spacer 14 and the insulation layer pattern 16 may remain as residues 22, as illustrated in FIG. 2. When the residues 22 remain on the spacer 14 and the insulation layer pattern 16, electrical reliability of the semiconductor device may be deteriorated. In this regard, the residues may be undesirable.

Further, the preliminary gate pattern 12 and the transition metal layer 18 may be dominantly reacted with each other in edge portions and the fully silicided gate pattern may not be easily formed to a desired thickness.

### SUMMARY OF THE INVENTION

Embodiments of the present invention provide methods of manufacturing a semiconductor device having a fully silicided gate pattern. In some embodiments, methods may include forming a layer including silicon on a substrate, forming a metal layer on the layer via an electroless plating process, and forming a metal silicide layer, via a reaction between the layer and the metal layer, by using a heat treatment process.

In some embodiments, the metal layer includes a material selected from the group consisting of tungsten, titanium, nickel and cobalt. In some embodiments, the heat treatment process is performed at a temperature in the range of about 300° C. to about 850° C.

Methods of manufacturing a semiconductor device according to some embodiments may include forming a preliminary gate pattern including silicon on a substrate, forming an insulation layer pattern on the substrate after forming the preliminary gate pattern, the insulation layer pattern exposing an upper face of the preliminary gate pattern, forming a metal layer on the upper face of the preliminary gate pattern by an electroless plating process, and forming a gate pattern including a metal silicide from a reaction between the preliminary gate pattern and the metal layer by performing a heat treatment process.

In some embodiments, the metal layer includes a material selected from the group consisting of tungsten, titanium, nickel and cobalt. In some embodiments, the heat treatment process is performed at a temperature in a range of about 300° C. to about 850° C. Performing the heat treatment process according to some embodiments includes performing a first heat treatment at a temperature in a range of about 300° C. to about 500° C. and performing a second heat treatment at a temperature in a range of about 400° C. to about 850° C. Some embodiments may include removing, after performing the first heat treatment, a portion of the metal layer that is not reacted with the preliminary gate pattern.

Some embodiments include forming a spacer on a sidewall of the preliminary gate pattern. Some embodiments include forming a capping layer on the insulation layer pattern to cover the metal layer, wherein the capping layer prevents the metal layer from reacting with the preliminary gate pattern at a portion of the insulation layer pattern that does not contact the preliminary gate pattern when performing the heat treatment process. In some embodiments, the capping layer includes titanium nitride.

Some embodiments of the present invention include methods of manufacturing a semiconductor device that include forming, on a substrate, first and second preliminary gate patterns that each include silicon and forming an insulation layer pattern on the substrate after forming the preliminary gate patterns, the insulation layer pattern exposing a first upper face of the first preliminary gate pattern and a second upper face of the second preliminary gate pattern. Embodiments of such methods may include forming a first metal layer on the first upper face of the first preliminary gate pattern by a first electroless plating process, forming a second metal layer on the second upper face of the second preliminary gate pattern by a second electroless plating process, forming, by a heat treatment process, a first gate pattern including a first metal silicide from a reaction between the first preliminary gate pattern and the first metal layer, and forming, by the heat treatment process, a second gate pattern including a second metal silicide from a reaction between the second preliminary gate pattern and the second metal layer.

In some embodiments, the first metal layer includes a first thickness, wherein the second metal layer includes a second thickness, and wherein the first thickness is substantially different from the second thickness. In some embodiments, the first and the second metal layers include at least one material selected from a group consisting of tungsten, titanium, nickel and cobalt, respectively.

In some embodiments, the heat treatment process is performed at a temperature in a range of about 300° C. to about 850° C. In some embodiments, the heat treatment process includes a first heat treatment performed at a temperature in a first temperature range of about 300° C. to about 500° C. and a second heat treatment performed at a temperature in a second temperature range of about 400° C. to about 850° C. Some embodiments may include removing, after performing the first heat treatment, a first portion of the first metal layer that is not reacted with the first preliminary gate pattern and a second portion of the second metal layer that is not reacted with the second preliminary gate pattern.

Some embodiments include forming spacers on sidewalls of the first and second preliminary gate patterns. Some embodiments include forming a capping layer on the insulation layer pattern to cover the first and second metal layers, wherein the capping layer prevents the metal layers from reacting with the preliminary gate patterns at a portion of the insulation layer pattern that does not contact the preliminary gate patterns when performing the heat treatment process. In some embodiments, the capping layer comprises titanium nitride.

### BRIEF DESCRIPTION OF THE DRAWINGS

FIG. 1 is a cross-sectional view illustrating a semiconductor device including a fully silicided gate pattern.

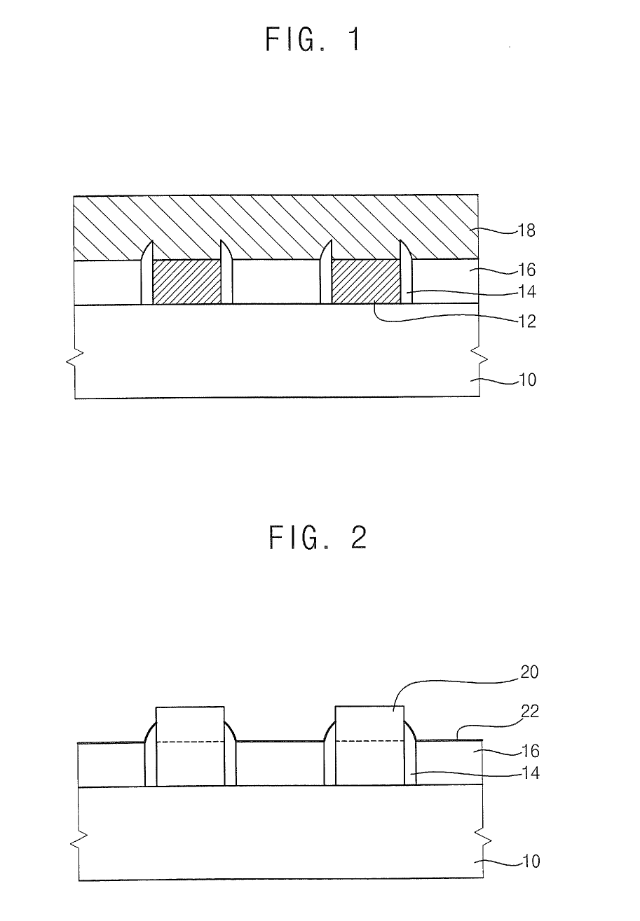

FIG. 2 is a cross-sectional view illustrating residues on an insulation layer pattern and a spacer that may be formed by a method of manufacturing a semiconductor device including a fully silicided gate pattern as illustrated in FIG. 1.

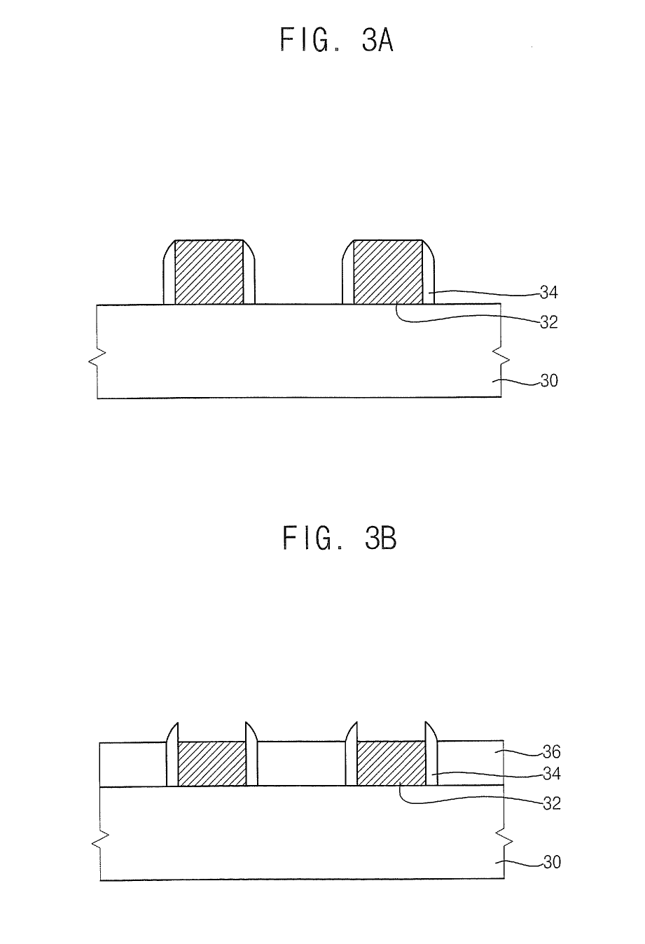

FIGS. 3A to 3D are cross-sectional views illustrating methods of manufacturing a semiconductor device including a fully silicided gate pattern in accordance with some embodiments of the present invention.

FIG. 4 is a cross-sectional view illustrating semiconductor devices having a metal layer illustrated in FIG. 3C and a capping layer on the insulation layer pattern to cover the metal layer in accordance with some embodiments of the present invention.

FIGS. 5A to 5C are cross-sectional views illustrating methods of manufacturing a semiconductor device including a fully silicided gate pattern in accordance with some embodiments of the present invention.

### DESCRIPTION OF THE EMBODIMENTS

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation. Like numbers refer to like elements throughout.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Some embodiments of the present invention are described herein with reference to cross-section illustrations that are schematic illustrations of idealized embodiments and intermediate structures of the present invention. As such, variations from the shapes of the illustrations as a result, for example, of manufacturing techniques and/or tolerances, may be expected. Thus, some embodiments of the present invention should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to limit the scope of the present invention.

Unless otherwise defined, all terms including technical and scientific terms used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

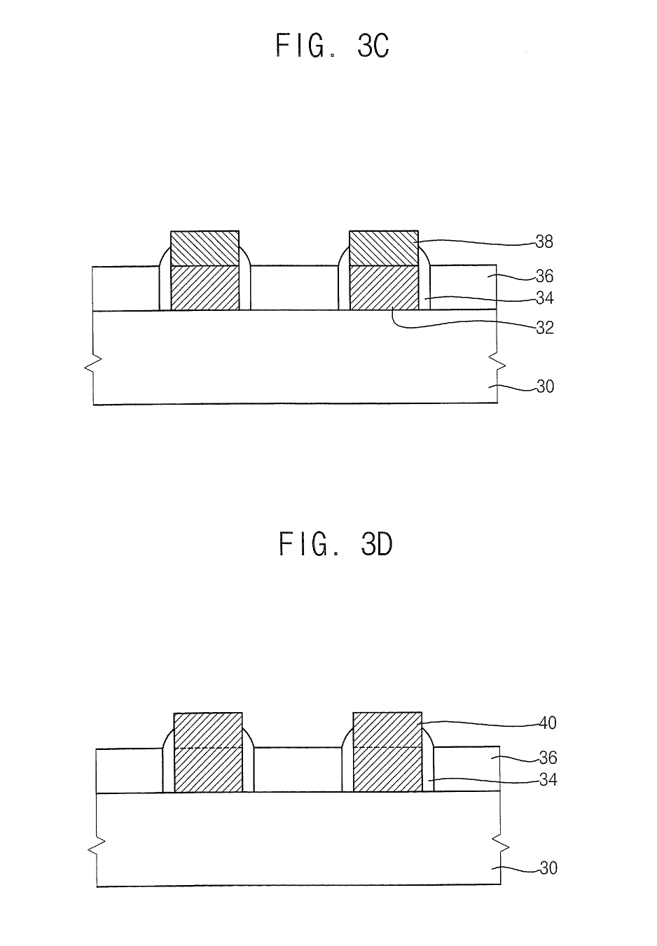

Reference is now made to FIGS. 3A through 3D, which are cross-sectional views illustrating methods of manufacturing semiconductor devices including a fully silicided gate pattern in accordance with some embodiments of the present invention. Referring to FIG. 3A, a preliminary gate pattern 32 may be formed on a substrate 30. The substrate 30 may include silicon, germanium, and silicon-germanium, among others. In some embodiments, the preliminary gate pattern 32 may be formed using polysilicon. A silicon layer may be formed on the substrate 30 and then patterned to form the preliminary gate pattern 32.

A spacer 34 may be formed on a sidewall of the preliminary gate pattern 32. The spacer 34 may be formed using, for example, silicon nitride. The spacer 34 may be formed by an etching process using an etching selectivity between silicon nitride and silicon or germanium. In some embodiments, the spacer 34 may not be formed on the sidewall of the preliminary gate pattern 32.

The preliminary gate pattern 32 may further include a gate insulation layer (not illustrated) therebeneath. In some embodiments, a source/drain region (not illustrated) may be formed at an upper portion of the substrate 30 adjacent the preliminary gate pattern 32. Furthermore, in some embodiments, a silicide layer (not illustrated) having a low resistance may be formed on the substrate 30 having the source/drain region.

Referring to FIG. 3B, an insulation layer pattern 36 exposing an upper face of the preliminary gate pattern 32 may be formed on the substrate 30 on which the preliminary gate pattern 32 is formed. The insulation layer pattern 36 may be formed by, for example, a deposition process and a planarization process.

In some embodiments, an insulation layer may be formed on the substrate 30 by the deposition process to cover the preliminary gate pattern 32. An upper portion of the insulation layer may be partially removed by the planarization process until the upper face of the preliminary gate pattern 32 is exposed. In some embodiments, the planarization process may include a chemical mechanical polishing (CMP) process. As a result, the insulation layer pattern 32 exposing the upper face of the preliminary gate pattern 32 may be formed on the substrate 30. When the spacer 34 is formed on the sidewall of the preliminary gate pattern 32, the insulation layer pattern 32 may also expose an upper portion of the spacer 34.

Referring to FIG. 3C, a metal layer 38 may be formed on the upper face of the preliminary gate pattern 32. In some embodiments, the metal layer 38 may have an etching selectivity with respect to silicon and oxide. The metal layer 38 may include a transition metal. In some embodiments, the transition metal includes tungsten, titanium, nickel, and/or cobalt, alone or in combination.

In some embodiments, the metal layer 38 may be formed by an electroless plating process. For example, the substrate 30 having the preliminary gate pattern 32 that has the exposed upper face may be immersed in a bath containing an electrolyte solution that includes metal. When the substrate 30 is immersed in the bath, the upper face of the preliminary gate pattern 32 is plated with metal, but the insulation layer pattern 36 and the spacer 34 are not plated with metal. In this manner, the metal layer 38 may be selectively formed on the upper face of the preliminary gate pattern 32 by the electroless plating process. A thickness of the metal layer 38 may be varied according to a design of a circuit pattern. In some embodiments, the metal layer 38 may be formed to a thickness of about 10 Å to about 1,000 Å.

Referring to FIG. 3D, after the metal layer 38 is selectively formed on the upper face of the preliminary gate pattern 32 by the electroless plating process, a heat treatment process may be performed on the substrate 30 having the preliminary gate pattern 32 and the metal layer 38 thereon. When the heat treatment process is performed at a temperature of less than about 300° C., the preliminary gate pattern 32 and the metal layer 38 may not be readily reacted with each other. When the heat treatment process is performed at a temperature greater than about 850° C., the substrate 30 may be damaged by heat. In some embodiments, the heat treatment process may be performed at a temperature of about 300° C. to about 850° C.

When the heat treatment process is performed, the preliminary gate pattern 32 and the metal layer 38 on the upper face of the preliminary gate pattern 32 are reacted with each other. That is, silicon included in the preliminary gate pattern 32 and metal included in the metal layer 38 are reacted with each other. Thus, the preliminary gate pattern 32 and metal layer 38 may be converted into a metal silicide layer by the heat treatment process. Accordingly, a gate pattern 40 including a metal silicide may be formed on the substrate 30 from the preliminary gate pattern 32 and metal layer 38. In this manner, a fully silicided gate pattern 40 may be formed on the semiconductor device 30.

In some embodiments, a heat treatment process including two separate processing steps may be performed. For example, a first step may be performed at a temperature of about 300° C. to about 500° C. and a second step may be performed at a temperature of about 400° C. to about 850° C. After the first step is performed, a portion of the metal layer 38 may not be reacted with the preliminary gate pattern 32. In some embodiments, the unreacted portion of the metal layer 38 may be removed by a wet etching process.

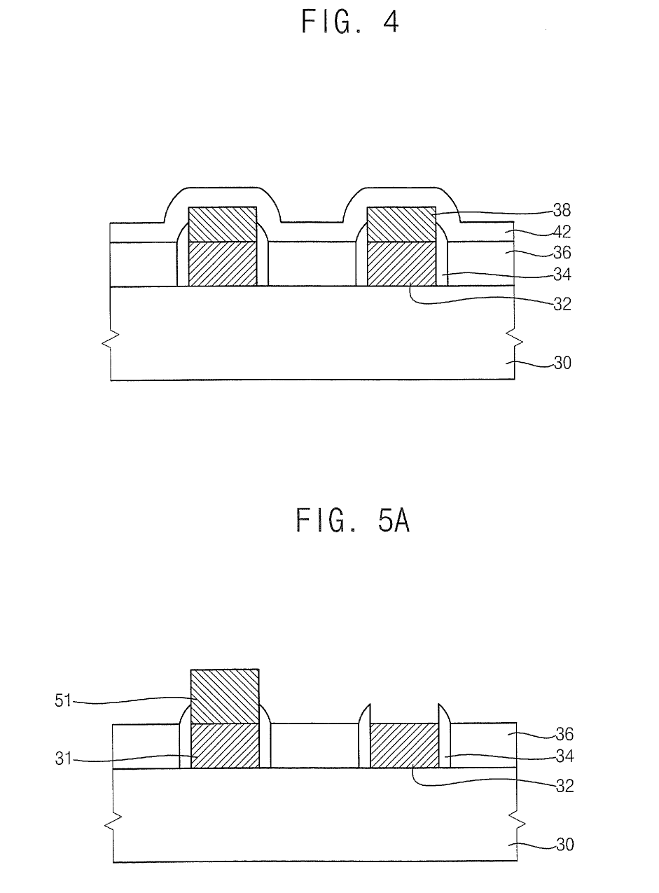

In some embodiments, after the metal layer 38 is formed on the upper face of the preliminary gate pattern 32, as illustrated in FIG. 3C, a capping layer 42 may be formed on the insulation layer pattern 36 to cover the metal layer 38 as illustrated in FIG. 4. The capping layer 42 may prevent the metal layer 38 from reacting with the preliminary gate pattern 32 at portions of the insulation layer pattern 36 and the spacer 34 that does not contact the preliminary gate pattern 32 by an out-diffusion of silicon when performing the heat treatment process. The capping layer 42 may be formed using, for example, titanium nitride.

In some embodiments, after the fully silicided gate pattern 40 is formed on the substrate 30 by the heat treatment process, a cleaning process may be further performed.

In some embodiments, a metal layer may be selectively formed on an upper face of a preliminary gate pattern, and a fully silicided gate pattern may be obtained from the preliminary gate pattern and the metal layer. In this manner, a semiconductor device including the fully silicided gate pattern, which has a reduced amount of residues on an insulation layer pattern or a spacer and has a controllable thickness, may be easily manufactured.

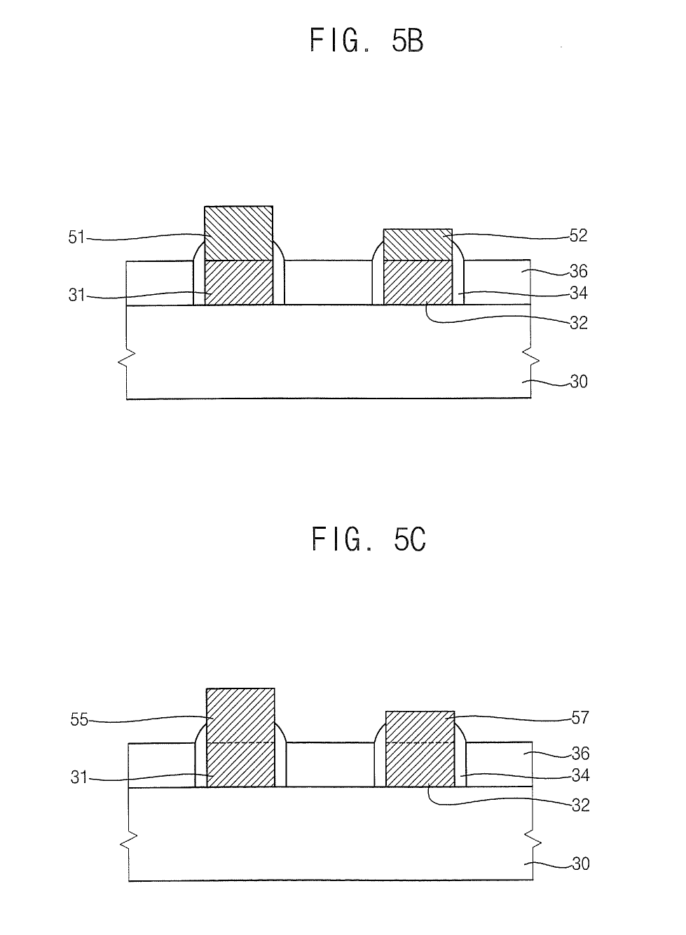

Reference is now made to FIGS. 5A to 5C, which are cross-sectional views illustrating methods of manufacturing semiconductor devices including a fully silicided gate pattern in accordance with some embodiments of the present invention. Embodiments as illustrated in FIGS. 5A to 5C have substantially similar elements as those of some embodiments illustrated in FIGS. 3A to 4. In this regard, like numerals refer to like elements throughout the above figures and detailed explanations about the same elements are omitted here in order to avoid repetitions.

Processes illustrated with reference to FIG. 3A to 3B may be performed, thereby forming an insulation layer pattern 36 on a substrate 30 to cover a plurality of preliminary gate patterns. The insulation layer pattern 36 exposes upper faces of the preliminary gate patterns. In some embodiments, two preliminary gate patterns 31 and 32 may be formed on the substrate 30. Each of the preliminary gate patterns 31 and 32 may be referred to as a first preliminary gate pattern 31 and a second preliminary gate pattern 32, respectively.

Referring to FIG. 5A, a first metal layer 51 may be formed on an upper face of the first preliminary gate pattern 31 by a first electroless plating process. For example, a first photoresist layer (not illustrated) is formed on the first and second preliminary gate patterns 31 and 32, the insulation layer pattern 36 and a spacer 34. The first photoresist layer may be patterned by a photolithography process to form a first photoresist layer pattern (not illustrated) that only exposes the upper face of the first preliminary gate pattern 31. The first electroless plating process may be performed to form a first metal layer 51 on the upper face of the first preliminary gate pattern 31. The first electroless plating process may be substantially similar to that illustrated with reference to FIG. 3C.

Referring FIG. 5B, a second metal layer 52 may be formed on an upper face of the second preliminary gate pattern 32 by a second electroless plating process. for example, a second photoresist layer (not illustrated) may be formed on the first metal layer 51, the second preliminary gate pattern 32, the insulation layer pattern 36 and the spacer 34. The second photoresist layer may be patterned by a photolithography process to form a second photoresist layer pattern (not illustrated) that only exposes the upper face of the second preliminary gate pattern 32. The second electroless plating process may be performed to form the second metal layer 52 on the upper face of the second preliminary gate pattern 32. In some embodiments, the second electroless plating process may be substantially the same as the first electroless plating process.

The first metal layer 51 may have a thickness different from that of the second metal layer 52. The thicknesses of the first and second metal layers 51 and 52 may be controlled by changing conditions during the electroless plating processes. In some embodiments, the first and the second metal layers 51 and 52 may include substantially the same materials. In some other embodiments, the first and the second metal layers 51 and 52 may include different materials. In some embodiments, the first metal layer 51 may include nickel and the second metal layer 52 may include cobalt. In some embodiments, the first and second metal layers 51 and 52 may include nickel.

After the first and second metal layers 51 and 52 are formed on the upper faces of the first and second preliminary gate patterns 31 and 32, respectively, a heat treatment process may be performed on the substrate 30 having the preliminary gate patterns 31 and 32 and the first and second metal layers 51 and 52 thereon.

In performing the heat treatment process, the first preliminary gate pattern 31 and the first metal layer 51 may be reacted with each other, and the second preliminary gate pattern 32 and the second metal layer 52 may be reacted with each other. As illustrated in FIG. 5C, a first gate pattern 55 including a first metal silicide may be formed from the first preliminary gate pattern 31 and the first metal layer 51, and a second gate pattern 57 including a second metal suicide may be formed from the second preliminary gate pattern 32 and the second metal layer 52. In this manner, a first fully silicided gate pattern 55 and a second fully silicided gate pattern 57 may be formed on the substrate 30.

According to some embodiments of the present invention, metal layers having thicknesses different from one another may be selectively formed on preliminary gate patterns, and thus fully silicided gate patterns having thicknesses different from one another may be obtained. In this manner, a semiconductor device including fully silicided gate patterns that have different but controllable thicknesses may be easily manufactured. Accordingly, a semiconductor device including a fully silicided gate pattern that has a reduced amount of residues on an insulation layer pattern or a spacer and has a controllable thickness may be easily manufactured.

According to some embodiments of the present invention, a semiconductor device including a fully silicided gate pattern, which has a reduced amount of residues on an insulation layer pattern or a spacer and has a controllable thickness, may be readily manufactured. In some embodiments, fully silicided gate patterns that have thicknesses different from one another may be formed on the semiconductor device. In this manner, a semiconductor device having enhanced electrical reliability may be manufactured.

Although the present invention has been described in terms of specific embodiments, thee present invention is not intended to be limited by the embodiments described herein. Thus, the scope may be determined by the following claims.

What is claimed is:

1. A method of manufacturing a semiconductor device, the method comprising:
forming a layer including silicon on a substrate;
forming a metal layer on the layer via an electroless plating process; and
forming a metal silicide layer, via a reaction between the layer and the metal layer, by using a heat treatment process.

2. The method of claim 1, wherein the metal layer comprises a material selected from the group consisting of tungsten, titanium, nickel and cobalt.

3. The method of claim 1, wherein the heat treatment process is performed at a temperature in the range of about 300° C. to about 850° C.

4. A method of manufacturing a semiconductor device, the method comprising:
forming a preliminary gate pattern including silicon on a substrate;
forming an insulation layer pattern on the substrate after forming the preliminary gate pattern, the insulation layer pattern exposing an upper face of the preliminary gate pattern;
forming a metal layer on the upper face of the preliminary gate pattern by an electroless plating process; and
forming a gate pattern including a metal silicide from a reaction between the preliminary gate pattern and the metal layer by performing a heat treatment process.

5. The method of claim 4, wherein the metal layer comprises a material selected from the group consisting of tungsten, titanium, nickel and cobalt.

6. The method of claim 4, wherein the heat treatment process is performed at a temperature in a range of about 300° C. to about 850° C.

7. The method of claim 6, wherein performing the heat treatment process comprises:
performing a first heat treatment at a temperature in a range of about 300° C. to about 500° C.; and
performing a second heat treatment at a temperature in a range of about 400° C. to about 850° C.

8. The method of claim 7, further comprising removing, after performing the first heat treatment, a portion of the metal layer that is not reacted with the preliminary gate pattern.

9. The method of claim 4, further comprising forming a spacer on a sidewall of the preliminary gate pattern.

10. The method of claim 4, further comprising forming a capping layer on the insulation layer pattern to cover the metal layer, wherein the capping layer prevents the metal layer from reacting with the preliminary gate pattern at a portion of the insulation layer pattern that does not contact the preliminary gate pattern when performing the heat treatment process.

11. The method of claim 10, wherein the capping layer comprises titanium nitride.

12. A method of manufacturing a semiconductor device, the method comprising:
forming, on a substrate, first and second preliminary gate patterns that each include silicon;
forming an insulation layer pattern on the substrate after forming the preliminary gate patterns, the insulation layer pattern exposing a first upper face of the first preliminary gate pattern and a second upper face of the second preliminary gate pattern;
forming a first metal layer on the first upper face of the first preliminary gate pattern by a first electroless plating process;
forming a second metal layer on the second upper face of the second preliminary gate pattern by a second electroless plating process;
forming, by a heat treatment process, a first gate pattern including a first metal silicide from a reaction between the first preliminary gate pattern and the first metal layer; and
forming, by the heat treatment process, a second gate pattern including a second metal silicide from a reaction between the second preliminary gate pattern and the second metal layer.

13. The method of claim 12, wherein the first metal layer comprises a first thickness, wherein the second metal layer comprises a second thickness, and wherein the first thickness is substantially different from the second thickness.

14. The method of claim 12, wherein the first and the second metal layers comprise at least one material selected from the group consisting of tungsten, titanium, nickel and cobalt, respectively.

15. The method of claim 12, wherein the heat treatment process is performed at a temperature in a range of about 300° C. to about 850° C.

16. The method of claim 15, wherein the heat treatment process comprises:
a first heat treatment performed at a temperature in a first temperature range of about 300° C. to about 500° C.; and
a second heat treatment performed at a temperature in a second temperature range of about 400° C. to about 850° C.

17. The method of claim 16, further comprising removing, after performing the first heat treatment, a first portion of the first metal layer that is not reacted with the first preliminary gate pattern and a second portion of the second metal layer that is not reacted with the second preliminary gate pattern.

18. The method of claim 12, further comprising forming spacers on sidewalls of the first and second preliminary gate patterns.

19. The method of claim 12, further comprising forming a capping layer on the insulation layer pattern to cover the first and second metal layers, wherein the capping layer prevents the metal layers from reacting with the preliminary gate patterns at a portion of the insulation layer pattern that does not contact the preliminary gate patterns when performing the heat treatment process.

20. The method of claim 19, wherein the capping layer comprises titanium nitride.
